(19) United States
(12) Patent Application Publication
(10) Pub. No.: US 2018/0312960 A1
(43) Pub. Date: Nov. 1, 2018

(54) METHOD OF MAKING LOW RESISTIVITY TUNGSTEN SPUTTER TARGETS AND TARGETS MADE THEREBY

(71) Applicant: Tosoh SMD, Inc., Grove City, OH (US)

(72) Inventors: Eugene Y. Ivanov, Grove City, OH (US); Eduardo del Rio, Dublin, OH (US)

(21) Appl. No.: 15/770,302

(22) PCT Filed: Oct. 17, 2016
(86) PCT No.: PCT/US2016/057311

§ 371 Date: Apr. 23, 2018

Related U.S. Application Data
(60) Provisional application No. 62/246,665, filed on Oct. 27, 2015.

(51) Int. Cl. C23C 14/34; B22F 3/16; H01J 37/34; C23C 14/14

(52) U.S. Cl. CPC C23C 14/3414; B22F 3/162; B22F 2301/20; H01J 37/3491; C23C 14/14; H01J 37/3426

(57) ABSTRACT

Tungsten sputter targets have a purity of greater than four nines, a density of about 97% and higher, and an oxygen content of 10 ppm or less. Method of making such targets from powder precursors are disclosed wherein the tungsten powder is pressure consolidated such as by CIPing following by a sintering step under a hydrogen atmosphere to control oxygen and carbon content of the target.

### CROSS-REFERENCE TO RELATED APPLICATION

This application claims the priority benefit of U.S. Provisional Patent Application Ser. No. 62/246,665 filed Oct. 27, 2015.

### FIELD OF INVENTION

The present invention pertains to tungsten sputter targets and methods of making same that exhibit reduced oxygen content, thereby decreasing target resistivity and resistivity of films produced from such targets.

### BACKGROUND OF THE INVENTION

Electrodes and interconnects made of tungsten are becoming increasingly popular. In general, these electrodes and interconnects are made by sputtering techniques wherein tungsten films are sputter coated onto the desired substrate.

It is desirable to produce low resistivity tungsten films. Film resistivity depends on purity of the metal, grain size in the film (larger is better), and sputtering parameters which can influence formation of high resistivity beta phase in the film.

It is known that sputter target microstructure can influence film uniformity. It is also known that presence of beta-phase W in the film can increase the film resistivity. This beta-phase, which is a high resistivity phase, can be stabilized by the presence of oxygen. Thus, it is desirable to reduce oxygen in the sputtering target and the films that are produced by sputtering of such targets.

### SUMMARY OF THE INVENTION

In accordance with one aspect of the invention, sputtered tungsten thin films are improved with regard to lower resistivity. Oxygen reduction and carbon reduction in the W material are beneficial and improve the performance of tungsten targets fabricated by press-sinter processes and thermo-mechanical processes such as rolling, forging, and extrusion.

In one exemplary embodiment, a tungsten sputter target is provided wherein the target has a purity of at least 99.99%, and the sputter target is further characterized by having an oxygen content of less than 10 ppm or even less than 8 ppm. In some embodiments, the tungsten sputter target of the invention has an oxygen content of about 4-6 ppm.

Additionally, in other embodiments, the purity of the tungsten target is about 99.999%, and the combined oxygen content and carbon content of the target is less than 20 ppm.

Films sputtered by sputter targets in accordance with the invention have resistivities of less than 9 micro Ohm cm. Further, in other aspects of the invention, the sputter targets comprise grain sizes of about 50-200 μm, and the targets may be further characterized, in certain embodiments, by the absence of subgrains with low angle subgrain boundaries within coarse grains.

In other embodiments, methods are provided for making a tungsten sputter target from precursor tungsten powder. The tungsten powder is subjected to a pressure consolidation step to form a green body. The green body is then sintered under a hydrogen atmosphere to reduce oxides from the tungsten. The sintered green body is then thermo-mechanically processed such as by rolling to form a target blank, and then the final desired shape is imparted to the target blank via machining or the like to form the final desired shape and configuration of the target.

In further embodiments of the invention, the pressure consolidation step comprises a cold isostatic pressure (CIP) step. This CIP step may be conducted at a pressure of about 30,000 psi for about three hours.

In some embodiments, the sintering step is conducted at temperatures of about 1450-1900° C. for about 1-5 hours under a controlled hydrogen atmosphere.

In other embodiments, the rolling step comprises a hot rolling conducted at temperatures of about 1500° C. In some instances, the rolling step may be conducted under an inert gas blanket such as argon.

### BRIEF DESCRIPTION OF THE DRAWING

FIG. 1 is a graph showing oxygen content of tungsten targets and resistivity of films sputtered thereby in accordance with the invention.

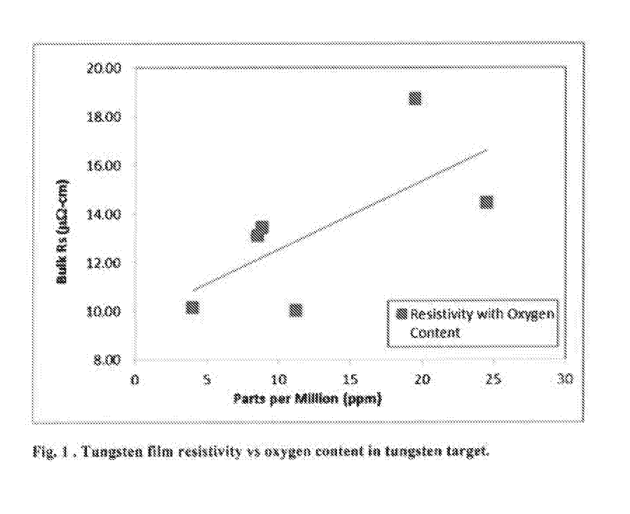

### DETAILED DESCRIPTION

In order to provide low resistivity W targets and thin films made by such sputter targets, it is desirable to decrease the amount of beta-W in the target. To this end, it is important to control or decrease oxygen content of the materials during the target fabrication process. In one embodiment of the invention, the target material is hydrogen treated in order to control the oxygen content of the W target.

In one embodiment of the invention, W powder is pressed in a rubber bag and subjected to CIP (cold isostatic pressure) usually under H₂O at about 30,000 psi for about three hours. Density of the material at this point is about 75-85%. The resulting green body is then sintered under hydrogen (i.e., hydrogen treated) to increase the strength, increase density to about 95%, and remove oxides from the W. In order to improve oxygen removal from the sintered material, very dry hydrogen is used having a very low dew point.

The sintering may be conducted at temperatures of about 1450-1900° C., for about 1-5 hours or longer, preferably under a H₂ gas atmosphere.

Next, the sintered W body is rolled to increase the density to close to 100%. This process requires about 1500° C. and sometimes is conducted under a protective (e.g., Ar) blanket.

In some embodiments of the present invention, oxygen of the W target is controlled so that it is less than 10 ppm, more preferably, less than 8 ppm and even more preferably at about 4-6 ppm.

In certain aspects, C levels are monitored and controlled via hydrogen treatment. C functions as a grain refiner with lower C amounts resulting in larger target grains which in turn lower resistivity. Thus, it is desirable to control C content to less than or equal to 30 ppm with a range of C content of less than or equal to 20 ppm being even more preferred.

After the sintering step, a target blank is provided that then can be given the desired shape or configuration for usage as a sputter target via machining and the like. Once machined, the target blank can be bonded to a backing plate using known methods such as soldering with a lead/tin or indium/tin solder, diffusion bonding, explosion bonding, etc.

The sputter targets so made have a purity of at least four nines and a density of at least 97%, preferably at least about 99%. The combined 02 and C level of the target may be less than 20 ppm and films produced by sputtering of such targets may have a resistivity of less than 9 micro Ohm cm.

While the present invention has been described with respect to particular examples, it is apparent that numerous other forms and modifications of the invention will be obvious to those skilled in the art. The appended claims and this invention should be construed to cover all such obvious forms and modifications.

1. A sputter target comprising a W metal target wherein said target has a purity of at least 99.99 wt %, said sputter target having an oxygen content of less than 10 ppm.

2. A sputter target as recited in claim 1 wherein said oxygen content is less than 8 ppm.

3. A sputter target as recited in claim 2 wherein said oxygen content is about 4-6 ppm.

4. A sputter target as recited in claim 1 wherein said target has a purity of about 99.999% and a combined oxygen content and carbon content of said target is less than 20 ppm.

5. A sputter target as recited in claim 4 wherein film produced from sputtering of said target has a resistivity of less than 9 micro Ohm cm.

6. A sputter target as recited in claim 4 wherein said target is comprised of grains of about 50-200 μm.

7. A sputter target as recited in claim 5 wherein said target is further characterized by the absence of subgrains with low angle subgrain boundaries within coarse grains.

8. A method of making a tungsten sputter target comprising providing a tungsten powder, subjecting said tungsten powder to pressure consolidation to form a green body, sintering said green body under a hydrogen atmosphere to reduce oxides from said tungsten, thermo-mechanically processing the sintered W green body to form a target blank and then providing a desired shape to said target blank to make said tungsten sputter target.

9. A method as recited in claim 8 wherein said pressure consolidation comprises cold isostatic pressure (CIP).

10. A method as recited in claim 8 wherein said CIP is conducted at a pressure of 30,000 psi for about three hours.

11. A method as recited in claim 10 wherein said sintering is conducted at a temperature of about 1450-1900° C. for about 1-5 hours.

12. A method as recited in claim 10 wherein said thermo-mechanical process comprises hot rolling at a temperature of about 1500° C.

13. A method as recited in claim 12 wherein said hot rolling is conducted under an inert gas.

14. A method as recited in claim 13 wherein said inert gas is Ar.

15. A method as recited in claim 8 wherein said sputter target has an oxygen content of less than 10 ppm, and a purity of about 99.999%.
